(19) United States
(12) Patent Application Publication
(10) Pub. No.: US 2016/0141531 A1
(43) Pub. Date: May 19, 2016

(54) THIN FILM TRANSISTOR

(71) Applicant: SHARP KABUSHIKI KAISHA, Osaka (JP)

(72) Inventor: Yasumori FUKUSHIMA, Osaka (JP)

(73) Assignee: Sharp Kabushiki Kaisha, Osaka (JP)

(21) Appl. No.: 14/899,774

(22) PCT Filed: Jun. 19, 2014
(86) PCT No.: PCT/JP2014/066267

§ 371 Date: Dec. 18, 2015

(30) Foreign Application Priority Data
Jun. 26, 2013 (JP) 2013-133720

(51) Int. Cl. H01L 51/05; H01L 51/10

(52) U.S. Cl. CPC H01L 51/0545; H01L 51/105

(57) ABSTRACT

A thin film transistor includes: a gate electrode; a gate insulating layer that covers the gate electrode; a source electrode and a drain electrode that are provided on the gate insulating layer; and an organic semiconductor layer that has a channel region between the source electrode and the drain electrode. The source electrode and the drain electrode each include a first conductive layer that increases adhesion with the gate insulating layer; a second conductive layer that has low electrical resistance; and a third conductive layer that make ohmic contact with the organic semiconductor layer. The third conductive layer has a first contact surface that contacts the gate insulating layer, and a second contact surface that contacts a side face of the first conductive layer and a side face of the second conductive layer facing the channel region.

### TECHNICAL FIELD

The present invention relates to a thin film transistor, and particularly relates to a thin film transistor that includes an organic semiconductor layer as a semiconductor layer.

### BACKGROUND ART

Conventionally, active matrix backplanes, in which switching elements are disposed in a grid pattern, have been widely used in order to perform display in thin display devices such as thin displays, thin tablet displays, and electronic paper.

In addition, thin film transistors, for example, have been provided as switching elements in each pixel, which is the smallest unit of an image, on a thin film transistor substrate. Furthermore, mainly inorganic semiconductor materials, such as amorphous silicon, polysilicon, and oxide semiconductors such as indium gallium zinc oxide, for example, have been used in semiconductor layers (active layers) of thin film transistors used in switching elements.

However, when thin film transistors that include inorganic semiconductor materials are manufactured, vacuum-type devices are used and high temperature processing is also required. As a result, production costs increase and certain limitations, such as needing a substrate that is heat-resistant, arise. In addition, since inorganic semiconductor materials and inorganic insulating materials are used, if the substrate is warped, for example, cracks are more likely to form, which means that such a substrate is not suitable for a flexible display device.

Therefore, it has been proposed in recent years to use organic thin film transistors that include an organic semiconductor layer formed from organic semiconductor materials (also abbreviated as “organic thin film transistors”). These organic thin film transistors can be formed at a low temperature (less than 200° C.); thus, substrate selectively can be increased and the organic semiconductor layer can be formed using a coating process. As a result, it is possible to reduce production costs. In addition, such a transistor may be applied to a flexible display device since the organic material (organic semiconductor layer, organic insulating film, or the like) that forms the device is flexible.

In such an organic thin film transistor, it is important to lower the connective resistance between the organic semiconductor layer and the source/drain electrode in order to stabilize the operation of the transistor. Thus, it is important to form good ohmic contact between the organic semiconductor and the source/drain electrode.

In order to form good ohmic contact, when a p-type organic semiconductor layer is used, it is preferable that the source electrode and the drain electrode be formed using a metal material that has a work function close to the HOMO (highest occupied molecular orbital) level (˜5 eV) of the organic semiconductor material. It is preferable to use platinum, nickel, gold, palladium, or the like as the metal material.

Furthermore, in order to form good ohmic contact, when an n-type organic semiconductor film is used, it is preferable to form the source electrode and the drain electrode by using a metal material that has a work function close to the LUMO (lowest unoccupied molecular orbital) level (˜3 eV) of the organic semiconductor material. It is preferable to use magnesium, neodymium, calcium, strontium, or the like as the metal material.

However, the above-mentioned metals used to form ohmic contact, such as platinum, nickel, gold, and palladium, do not adequately adhere to backing members such as substrates and insulating layers. Thus, there is demand to improve the adhesion between backing members and the source/drain electrode.

Japanese Patent Application Laid-Open Publication No. 2006-147613 (Patent Document 1) and Japanese Patent Application Laid-Open Publication No. 2006-59896 (Patent Document 2), for example, disclose thin film transistors that include an adhesive layer with favorable adhesion to backing members in order to improve the adhesion between the backing members and the source/drain electrode.

The organic thin film transistor disclosed in Patent Document 1 includes: a gate electrode formed on a substrate; a gate insulating layer formed on the substrate so as to cover the gate electrode; a source electrode and drain electrode formed so as to face each other on the gate insulating layer; and an organic semiconductor layer formed on the gate insulating layer between the source electrode and drain electrode so as to be continuous with the source electrode and the drain electrode.

A channel region is formed in the organic semiconductor layer between the source electrode and the drain electrode. The source electrode and the drain electrode respectively include: an adhesive layer that adheres well to the gate insulating layer and that is formed on the gate insulating layer; and an ohmic contact layer that is formed on the gate insulating layer so as to contact the channel region and so as to cover a side face of the adhesive layer that faces the channel region.

In addition, the organic thin film transistor disclosed in Patent Document 2 is different from the thin film transistor disclosed in Patent Document 1 in that the structure of the source electrode and the drain electrode is different. Entire respective portions of the source electrode and the drain electrode that contact the gate insulating layer are formed via the adhesive layer. Specifically, the source electrode and the drain electrode respectively include: an adhesive layer that adheres well to the gate insulating layer and that is formed on the gate insulating layer; and a conductive layer and an ohmic contact layer formed on the adhesive layer. The ohmic contact layer contacts both the adhesive layer and the side face of the conductive layer that faces the channel.

### RELATED ART DOCUMENTS

### Patent Documents

Patent Document 1: Japanese Patent Application Laid-Open Publication No. 2006-147613

Patent Document 2: Japanese Patent Application Laid-Open Publication No. 2006-59896

### SUMMARY OF THE INVENTION

### Problems to be Solved by the Invention

In recent years, there has been demand for faster driving in thin film transistors. In order to realize such a driving speed, it is necessary to reduce the connective resistance between the organic semiconductor layer and the source/drain electrode, and to reduce the electrical resistance of the source electrode and drain electrode themselves and the electrical resistance of wiring that connects these electrodes.

In the organic thin film transistor disclosed in Patent Document 1, the adhesive layer, which constitutes a large portion of the source electrode and the drain electrode, is formed using a metal with a relatively high electrical resistance, such as titanium, chromium, or nickel. Such metals do not have a sufficiently low enough electrical resistance, however. Thus, there is concern that it will be difficult to realize a high driving speed in the organic thin film transistor disclosed in Patent Document 1.

In addition, in the organic thin film transistor disclosed in Patent Document 2, the adhesive layer is formed at a thickness of 1 to 3 nm. It is extremely difficult to control the thickness of this film, however. Even in instances in which it is possible to successfully form an adhesive layer with such a thickness, there is concern that the adhesion and mechanical strength with respect to the base cannot be ensured.

Furthermore, if there are variations in the thickness of the adhesive layer such that the layer becomes thicker, there is concern that the ohmic contact layer formed on the adhesive layer will not function adequately, and that there will be an increase in the contact resistance between the organic semiconductor layer and the source/drain electrode.

The present invention takes into consideration the above-mentioned problems. An aim of the present invention is to provide an organic thin film transistor that increases the adhesion between the base and the source/drain electrode, and that is able to realize an increase in driving speed.

### Means for Solving the Problems

A thin film transistor according to the present invention includes, in one aspect: a substrate having a main surface; a gate electrode provided on the main surface; a gate insulating layer provided on the main surface so as to cover the gate electrode; a source electrode and a drain electrode provided on the gate insulating layer so as to face each other and such that at least a portion of each overlaps the gate electrode through the gate insulating layer; and an organic semiconductor layer provided so as to cover a portion of the gate insulating layer located between the source electrode and the drain electrode, and so as to straddle the source electrode and the drain electrode at respective tops thereof, wherein the organic semiconductor layer includes a channel region formed so as to overlap the gate electrode between the source electrode and the drain electrode, wherein the source electrode and the drain electrode include: a first conductive layer that increases adhesion with the gate insulating layer; a second conductive layer that is stacked on the first conductive layer and that has an electrical resistance lower than the first conductive layer; and a third conductive layer that is provided on a side of the first conductive layer and a side of the second conductive layer, both of which face the channel region, the third conductive layer making ohmic contact with the organic semiconductor layer, and wherein the third conductive layer has a first contact surface that contacts the gate insulating layer, and a second contact surface that contacts a side face of the first conductive layer and a side face of the second conductive layer facing the channel region.

In the thin film transistor according to a first aspect of the present invention, it is preferable that the third conductive layer be formed of a portion that extends along the side face of the first conductive layer and the side face of the second conductive layer opposite to where the gate insulating layer is located, and a portion that extends along the gate insulating layer opposite to where the first conductive layer is located.

A thin film transistor according to the present invention includes, in a second aspect: a substrate having a main surface; a source electrode and a drain electrode provided on the main surface so as to face each other; an organic semiconductor layer provided so as to cover a portion of the substrate located between the source electrode and the drain electrode, and so as to straddle the source electrode and the drain electrode at respective tops thereof; a gate insulating layer provided on the main surface so as to cover the source electrode, the drain electrode, and the organic semiconductor layer; and a gate electrode provided on the gate insulating layer so as to overlap, through the gate insulating layer, at least a portion of the source electrode and the drain electrode, and the organic semiconductor layer located between the source electrode and the drain electrode, wherein the organic semiconductor layer includes a channel region provided so as to overlap the gate electrode between the source electrode and the drain electrode, wherein the source electrode and the drain electrode include: a first conductive layer that increases adhesion with the substrate; a second conductive layer that is stacked on the first conductive layer and that has an electrical resistance lower than the first conductive layer; and a third conductive layer that is provided on a side of the first conductive layer and a side of the second conductive layer, both of which face the channel region, the third conductive layer making ohmic contact with the organic semiconductor layer, and wherein the third conductive layer has a first contact surface that contacts the main surface of the substrate, and a second contact surface that contacts a side face of the first conductive layer and a side face of the second conductive layer facing the channel region.

In the thin film transistor according to the second aspect of the present invention, it is preferable that the third conductive layer be formed of a portion that extends along the side face of the first conductive layer and the side face of the second conductive layer opposite to where the substrate is located, and a portion that extends along the substrate opposite to where the first conductive layer is located.

In the thin film transistors according to the first aspect and second aspect of the present invention, it is preferable that the third conductive layer protrude in a direction heading away from a border of the first contact surface and the second contact surface.

### Effects of the Invention

According to the present invention, it is possible to provide an organic thin film transistor that can increase the adhesion between a base and a source/drain electrode, and that can realize a faster driving speed.

### BRIEF DESCRIPTION OF THE DRAWINGS

FIG. 1 shows a liquid crystal display device that includes a thin film transistor substrate provided with a thin film transistor according to Embodiment 1 of the present invention.

FIG. 2 illustrates the main components of the liquid crystal display device and the thin film transistor substrate shown in FIG. 1.

FIG. 3 is a schematic plan view of the thin film transistor substrate shown in FIG. 1.

FIG. 4 is a schematic cross-sectional view along the line IV-IV shown in FIG. 3.

FIG. 5 illustrates a state of an insulating substrate during a manufacturing process of the thin film transistor substrate shown in FIG. 1 after completion of the step of forming a gate electrode, the step of forming a gate insulating layer, and Step 1 of forming a source electrode and a drain electrode.

FIG. 6 illustrates Step 2 of forming the source electrode and the drain electrode during the manufacturing process of the thin film transistor substrate shown in FIG. 1.

FIG. 7 illustrates Step 3 of forming the source electrode and the drain electrode during the manufacturing process of the thin film transistor substrate shown in FIG. 1.

FIG. 8 illustrates Step 4 of forming the source electrode and the drain electrode during the manufacturing process of the thin film transistor substrate shown in FIG. 1.

FIG. 9 is a schematic cross-sectional view of a thin film transistor substrate that includes a thin film transistor according to Embodiment 2 of the present invention.

FIG. 10 illustrates Step 2A of forming a source electrode and a drain electrode during the manufacturing process of the thin film transistor substrate shown in FIG. 9.

FIG. 11 illustrates Step 3A of forming the source electrode and the drain electrode during the manufacturing process of the thin film transistor substrate shown in FIG. 9.

FIG. 12 is a schematic cross-sectional view of a thin film transistor substrate that includes a thin film transistor according to Embodiment 3 of the present invention.

FIG. 13 illustrates the state of a source electrode, an organic thin film semiconductor layer, and a gate insulating layer after the thin film transistor substrate shown in FIG. 12 has been bent.

FIG. 14 shows Step 2B of forming the source electrode and the drain electrode during the manufacturing process of the thin film transistor substrate shown in FIG. 12.

FIG. 15 shows Step 3B of forming the source electrode and the drain electrode during the manufacturing process of the thin film transistor substrate shown in FIG. 12.

FIG. 16 shows Step 4B of forming the source electrode and the drain electrode during the manufacturing process of the thin film transistor substrate shown in FIG. 12.

FIG. 17 shows Step 5B of forming the source electrode and the drain electrode during the manufacturing process of the thin film transistor substrate shown in FIG. 12.

FIG. 18 is a schematic cross-sectional view of a thin film transistor substrate that includes a thin film transistor according to Embodiment 4 of the present invention.

FIG. 19 shows Step 1C of forming a source electrode and a drain electrode during the manufacturing process of the thin film transistor substrate shown in FIG. 18.

FIG. 20 shows Step 2C of forming the source electrode and the drain electrode during the manufacturing process of the thin film transistor substrate shown in FIG. 18.

FIG. 21 shows Step 3C of forming the source electrode and the drain electrode during the manufacturing process of the thin film transistor substrate shown in FIG. 18.

FIG. 22 shows Step 4C of forming the source electrode and the drain electrode during the manufacturing process of the thin film transistor substrate shown in FIG. 18.

FIG. 23 shows the state of an insulating substrate during the manufacturing process of the thin film transistor substrate shown in FIG. 18 after completion of the steps of forming an organic semiconductor layer, forming a gate insulating layer, forming a gate electrode, and forming a planarizing film.

FIG. 24 is a schematic cross-sectional view of a thin film transistor substrate that includes a thin film transistor substrate according to Embodiment 5 of the present invention.

FIG. 25 shows Step 2D of forming a source electrode and a drain electrode during the manufacturing process of the thin film transistor substrate shown in FIG. 24.

FIG. 26 shows Step 3D of forming the source electrode and the drain electrode during the manufacturing process of the thin film transistor substrate shown in FIG. 24.

FIG. 27 is a schematic cross-sectional view of a thin film transistor substrate that includes a thin film transistor according to Embodiment 6 of the present invention.

FIG. 28 shows Step 2E of forming the source electrode and the drain electrode during the manufacturing process of the thin film transistor substrate shown in FIG. 27.

FIG. 29 shows Step 3E of forming the source electrode and the drain electrode during the manufacturing process of the thin film transistor substrate shown in FIG. 27.

FIG. 30 shows Step 4E of forming the source electrode and the drain electrode during the manufacturing process of the thin film transistor substrate shown in FIG. 27.

FIG. 31 shows Step 5E of forming the source electrode and the drain electrode during the manufacturing process of the thin film transistor substrate shown in FIG. 27.

### DETAILED DESCRIPTION OF EMBODIMENTS

Below, embodiments and modification examples of the present invention will be explained in detail with reference to the drawings. It should be noted that, in the embodiments and modification examples described below, components that are the same or common throughout are given the same reference characters, and repeat explanations thereof will be omitted.

### Embodiment 1

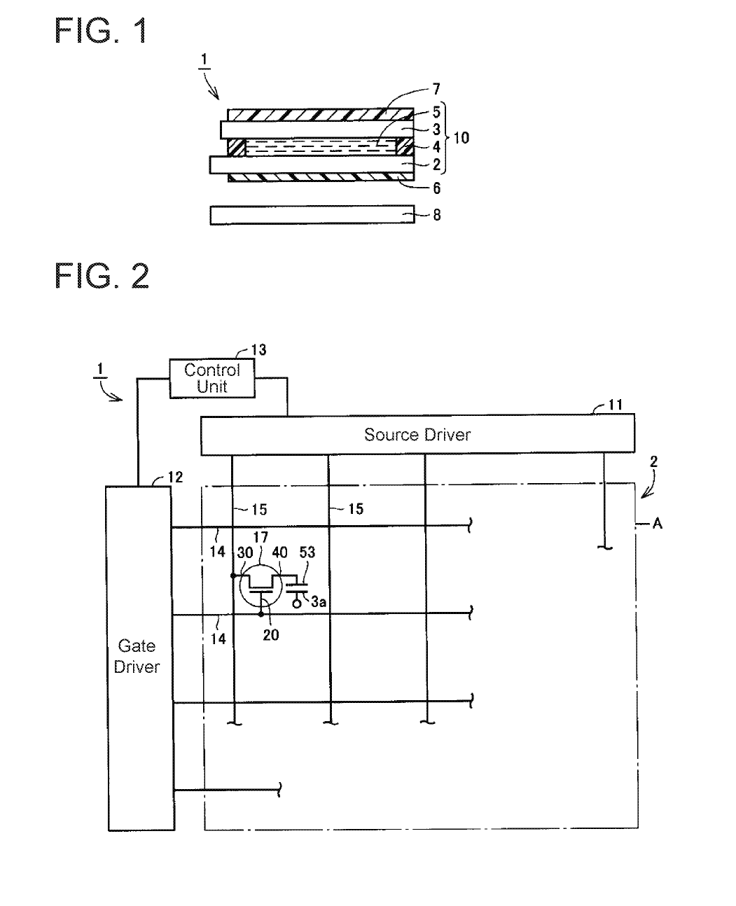

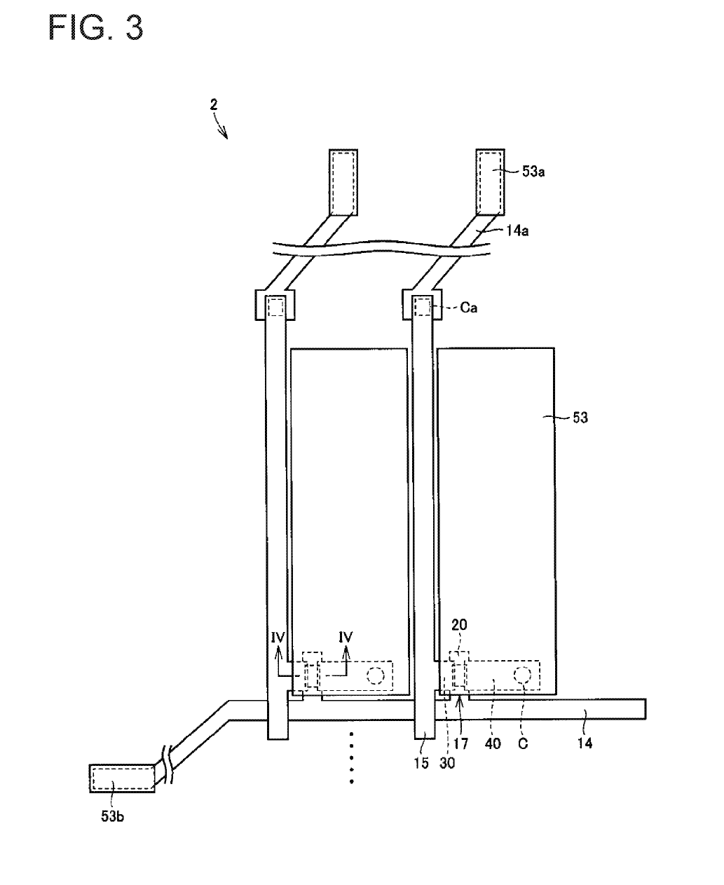

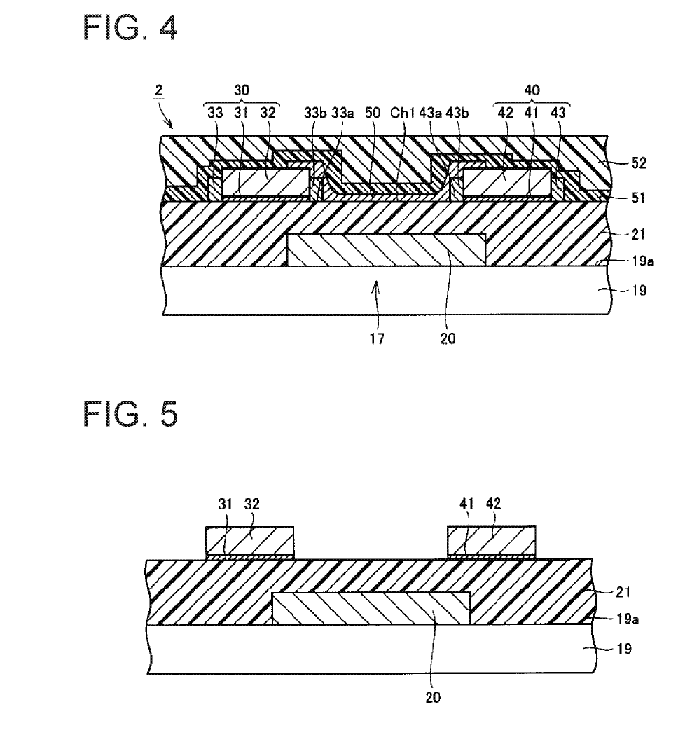

FIG. 1 shows a liquid crystal display device that includes a thin film transistor substrate provided with a thin film transistor according to the present embodiment. FIG. 2 illustrates the main components of the liquid crystal display device and the thin film transistor substrate shown in FIG. 1. FIG. 3 is a schematic plan view of the thin film transistor substrate shown in FIG. 1. FIG. 4 is a schematic cross-sectional view along the line IV-IV shown in FIG. 3. A thin film transistor substrate 2 and a liquid crystal display device 1 according to the present embodiment will be explained with reference to FIGS. 1 to 4.

As shown in FIG. 1, the liquid crystal display device 1 according to the present embodiment includes: a liquid crystal display panel 10; a polarizing plate 7 provided on one main surface of the liquid crystal display panel 10; a polarizing plate 6 provided on another main surface of the liquid crystal display panel 10; and a backlight unit 8 that emits light toward the liquid crystal display panel 10.

The liquid crystal display panel 10 includes: the thin film transistor substrate 2, which is disposed on a backlight unit 8 side of the liquid crystal display panel 10; an opposite substrate 3 that is disposed upon the thin film transistor substrate 2; a liquid crystal layer 5 disposed between the thin film transistor substrate 2 and the opposite substrate 3; and a sealing member 4 that bonds the thin film transistor substrate 2 and the opposite substrate 3 to each other and that is disposed in a loop so as to seal the liquid crystal layer 5 between the thin film transistor substrate 2 and the opposite substrate 3.

The opposite substrate 3 includes a transparent substrate such as a glass substrate; a color filter (not shown) formed on a main surface disposed on the liquid crystal layer 5 side; and an opposite electrode (not shown) formed on the color filter. An alignment film is provided on the opposite electrode to align the liquid crystals forming the liquid crystal layer 5.

As shown in FIG. 2, the liquid crystal display device 1 further includes: a control unit 13 that controls the driving of the liquid crystal display panel 10, which displays image data and the like; and a source driver 11 and a gate driver 12 that operate in accordance with signals from the control unit 13.

The source driver 11 and the gate driver 12 are driver circuits for driving individual pixels included in a plurality of pixels disposed on the liquid crystal display panel 10 side. To the outside of an active display area A of the liquid crystal display panel 10, the source driver 11 is connected to a plurality of signal wiring lines 15 via a plurality of source terminals 53a (see FIG. 3) disposed on the thin film transistor substrate 2. The gate driver 12 is connected to a plurality of scan wiring lines 14 via a plurality of gate terminals 53b (see FIG. 3) provided on the thin film transistor substrate 2.

As shown in FIGS. 2 to 4, the thin film transistor substrate 2 includes: the plurality of scan wiring lines 14, which are disposed so as mutually extend in parallel along an insulating substrate 19 (see FIG. 4); the plurality of signal wiring lines 15, which are disposed so as to mutually extend in parallel in a direction orthogonal to the scan wiring lines 14; thin film transistors 17 respectively provided near locations where the scan wiring lines 14 and the signal wiring lines 15 intersect; a passivation film 51 (see FIG. 4) provided so as to cover the thin film transistors 17; a planarizing film 52 (see FIG. 4) provided so as to cover the passivation film 51; and a plurality of pixel electrodes 53 (see FIG. 3) that are disposed in a matrix on the planarizing film 52 and that are respectively connected to the thin film transistors 17. An alignment film (not shown) for aligning the liquid crystals forming the liquid crystal layer 5 is provided on the pixel electrodes 53.

In addition, the thin film transistor 17 includes: a gate electrode 20; a source electrode 30; and a drain electrode 40. The gate electrode 20 is connected to the scan wiring line 14. The source electrode 30 is connected to the signal wiring line 15. The pixel electrode 53 is connected to the drain electrode 40 via a contact hole C.

As shown in FIG. 3, the scan wiring line 14 is connected to a gate terminal 53b, and the signal wiring line 15 is connected to the source terminal 53a by being connected to a relay wiring line 14a via a contact hole Ca provided in a gate insulating layer 21.

As shown in FIG. 2, in the various pixels in the liquid crystal display device 1, gate signals are transmitted from the gate driver 12 to the gate electrode 20 via the scan wiring line 14. If the organic thin film transistor is turned ON, source signals are transmitted from the source driver 11 to the source electrode 30 via the signal wiring line 15, and a prescribed electric charge is written to the pixel electrode 53 via an organic semiconductor layer 50 (see FIG. 4) and the drain electrode 40.

At this time, a difference in potential occurs between the respective pixel electrodes 53 on the thin film transistor substrate 2 and the opposite electrodes 3a (see FIG. 2) on the opposite substrate 3, resulting in a prescribed voltage being applied to the liquid crystal layer 5 (see FIG. 1).

Afterwards, in the liquid crystal display device 1, the alignment state of the liquid crystal layer 5 is modified in accordance with the magnitude of the voltage applied to the liquid crystal layer 5 in order to adjust the light transmittance of the liquid crystal layer 5, thereby displaying an image via the respective pixels.

As shown in FIG. 4, the thin film transistor 17 includes: the insulating substrate 19, which has a main surface 19a; a gate electrode 20 provided on the main surface 19a; a gate insulating layer 21 provided on the main surface 19a of the insulating substrate 19 so as to cover the gate electrode 20; a source electrode 30 and a drain electrode 40 that are provided so as to face each other on the gate insulating layer 21 and of which at least a respective portion overlaps the gate electrode 20 through the gate insulating layer 21; and the organic semiconductor layer 50, which is provided so as to cover a portion of the gate insulating layer 21 located between the source electrode 30 and the drain electrode 40 and so as to straddle the source electrode 30 and the drain electrode 40 from the top of the source electrode 30 to the top of the drain electrode 40.

The organic semiconductor layer 50 includes a channel region Ch1 formed so as to overlap the gate electrode 20 between the source electrode 30 and the drain electrode 40.

The source electrode 30 includes: a first conductive layer 31; a second conductive layer 32; and a third conductive layer 33. Additionally, the drain electrode 40 includes: a first conductive layer 41; a second conductive layer 42; and a third conductive layer 43.

The first conductive layer 31, 41 is formed on the gate insulating layer 21, and is formed using materials which adhere well to the gate insulating layer 21, which is the base layer. Metals such as Ti, TiN, TaN, and the like can be used as the materials that form the first conductive layer 31, 41.

The second conductive layer 32, 42 is formed on the first conductive layer 31, 41. The second conductive layer is formed of a material that has a lower electrical resistance than the first conductive layer 31. Metals that are relatively inexpensive and that have a low electrical resistance, such as Cu, Al, W, Mo, and the like, may be used as the materials that form the second conductive layer 32, 42.

The third conductive layer 33 is formed on the channel region Ch1 side of the first conductive layer 31 and the second conductive layer 32, and is formed of materials that form good ohmic contact with the organic semiconductor layer 50.

Metals such as platinum, nickel, gold, cobalt, palladium, silver, copper, molybdenum, and the like can be used as the materials to form the third conductive layer 33 when a p-type organic semiconductor is used as the organic semiconductor layer 50. When an n-type organic semiconductor is used as the organic semiconductor layer 50, strontium, calcium, neodymium, magnesium, hafnium, barium, or the like may be used.

The third conductive layer 33, 43 has a substantially rectangular cuboid shape, and includes: a first contact surface 33a, 43a that contacts the gate insulating layer 21; and a second contact surface 33b, 43b that contacts a side face of the first conductive layer 31, 41 and a side face of the second conductive layer 32, 42 that respectively face the channel region Ch1.

In addition, a p-type or n-type organic semiconductor layer may be used as the organic semiconductor layer 50. Pentacene, a pentacene derivative, a polythiophene, a phthalocyanine, a poly(2,5-bis(3-alkylthiophen-2-yl)thieno[3,2-b]thiophene) (PBTTT), or the like, for example, can be used as the material to form a p-type organic semiconductor layer. A perylene diimide derivative, fullerene, a fullerene derivative, or the like, for example, can be used as the material to form an n-type organic semiconductor layer.

In such a configuration, the third conductive layer 33, 43 can be disposed so as to be adjacent to the channel region Ch1 of the organic semiconductor layer 50 and so as to be able to reduce the contact resistance with the organic semiconductor layer 50. Thus, it is possible to further reduce the contact resistance between the organic semiconductor layer 50 and the source electrode 30 and the drain electrode 40.

In addition, a conductive layer is not specifically provided between the third conductive layer 33, 43 and the gate insulating layer 21 that is the base. As a result, there will not be any effects from variations in the thickness of such a layer that occur during production. This means that the contact resistance between the organic semiconductor layer 50 and the source electrode 30 and the drain electrode 40 will be stabilized, resulting in a stabilization of the operation of the thin film transistor 17.

In addition, a metal that is relatively inexpensive and that has a low electrical resistance is used as the second conductive layer 32, 42, which makes up a large portion of the source electrode 30, the drain electrode 40, and the signal wiring lines 15; thus, it is possible to reduce production costs and realize a thin film transistor 17 with a faster driving speed.

Moreover, as a result of the first conductive layer 31, 41, which adheres well to the gate insulating layer 21, being formed between the second conductive layer 32, 42 and the gate insulating layer 21, it is possible to improve adhesion with the base of the source electrode and the drain electrode.

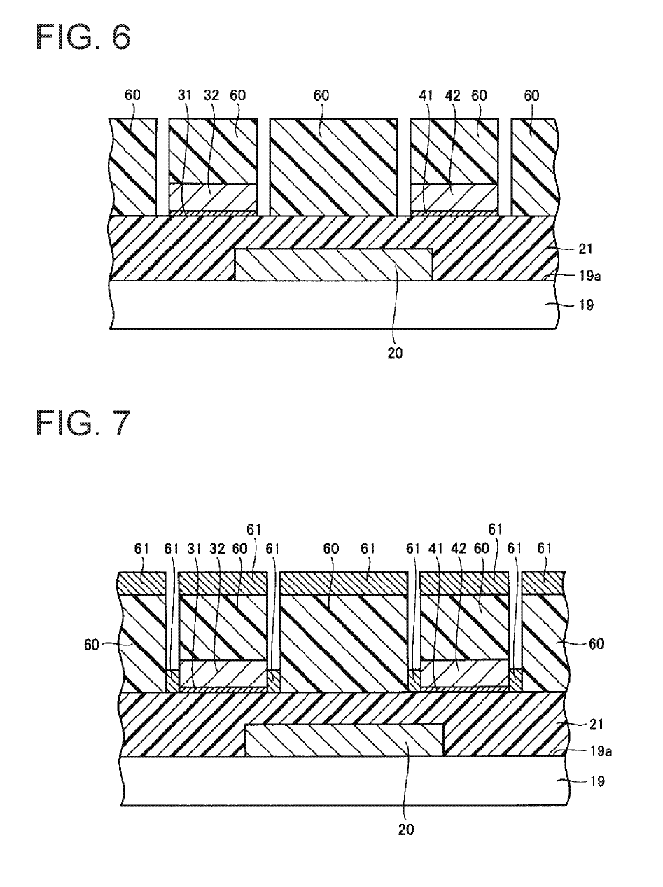

FIG. 5 illustrates a state of the insulating substrate during the manufacturing process of the thin film transistor substrate shown in FIG. 1 after completion of the step of forming the gate electrode, the step of forming the gate insulating layer, and Step 1 of forming the source electrode and the drain electrode. FIGS. 6 to 8 show Steps 2 to 4 of forming the source electrode and the drain electrode during the manufacturing process of the thin film transistor shown in FIG. 1. A method of manufacturing the thin film transistor substrate 2 that includes the thin film transistor 17 according to the present embodiment will be explained with reference to FIGS. 5 to 8.

As shown in FIG. 5, after completion of the step of forming the gate electrode, the step of forming the gate insulating layer, and Step 1 of forming the source electrode and the gate electrode, an insulating substrate 19 includes: the gate electrode 20, which is formed on the insulating substrate 19; the gate insulating layer 21, which is formed on the insulating substrate 19 so as to cover the gate electrode 20; and a portion of the source electrode and a portion of the drain electrode (the first conductive layer 31, 41 and the second conductive layer 32, 42) that are provided so as to face each other on the gate insulating layer 21 and respectively overlap the gate electrode 20 through the gate insulating layer 21.

The step of forming the gate electrode, the step of forming the gate insulating layer, and Step 1 of forming the source electrode and the drain electrode will be respectively explained next with reference to FIG. 5.

<Step of Forming Gate Electrode>

First, a film, such as a stacked film constituted of a Ti film and an Al film, is formed via sputtering, for example, on the main surface 19a of the insulating substrate 19 that is a glass substrate, a plastic substrate, or the like. Specifically, the film used to form the gate electrode 20 can be a Ti (top layer)/Al/Ti (bottom layer) stacked film with layer thicknesses of 30 nm/200 nm/5 nm from top to bottom.

However, the thickness of and the materials used to form the metal films in the stacked film are not limited to the examples mentioned above. For example, the thickness of the Al film may be approximately 100 nm to 400 nm, and a relatively inexpensive metal with a low electrical resistance such as Cu, W, Mo, or the like may be used instead of Al.

In addition, the thickness of the Ti bottom layer may be approximately 5 nm to 30 nm, for example, and a stacked film made of TaN, TiN, or the like that adheres well to the insulating substrate 19 (base) may be used instead of a single layer of Ti. Furthermore, the Ti top layer can have a thickness of approximately 30 nm to 100 nm, for example.

Next, the entire insulating substrate 19 on which the gate electrode film was formed is coated with a photosensitive resin film via spin coating, and a resist pattern is formed by subsequently exposing and developing the photosensitive resin film. Next, the gate electrode film protruding from the resist pattern is removed via wet etching. Afterwards, the gate electrode 20, the scan wiring line 14, and the relay wiring line 14a are formed on the main surface 19a of the insulating substrate 19 by removing the resist pattern. This is done by submerging the resist pattern in an etching fluid.

When wet etching is performed on the gate electrode film, an HF or oxidizing etchant can be used to etch Ti films, while an etchant that is a mixture of phosphoric acid, nitric acid, and acetic acid can used to etch Al films.

The pattern formation method of the gate electrode is not limited to the above-described method, and electroplating, electroless plating, printing that uses a conductive paste, or the like, may also be used.

If a plastic substrate is used as the insulating substrate 19, it is preferable to use as the material for forming the plastic substrate: a polyethylene terephthalate resin, a polyethylene resin, a naphthalate resin, a polyether sulfone resin, a polypropylene resin, a polycarbonate resin, a polyester resin, or the like, for example. By using such a material, it is possible to make the thin film transistor substrate 2 more lightweight, more flexible, and more transparent. The gate electrode may also be formed after a plastic substrate has been placed on a glass substrate.

<Step of Forming Gate Insulating Layer>

Next, the entire insulating substrate 19 on which the gate electrode 20 was formed is coated with an organic insulating material, such as a polyimide, a polyethylene, a polyvinyl phenol, or the like. The coated substrate is then baked for approximately several minutes to several dozen minutes at a temperature of approximately 100 to 150° C., which vaporizes the solvent. This forms a gate insulating film, with a thickness of approximately 100 nm to 1000 nm, that covers the gate electrode 20.

Next, a patterned resist is formed on the gate insulating film via photolithography, and wet etching or dry etching is performed on the gate insulating film. As a result, openings are formed such that the gate terminal and the source terminal are able to connect to the gate driver and the source driver. Openings are also formed in the vicinity of the source terminal such that the signal wiring lines 15 and the relay wiring line 14a are able to be electrically connected.

An ultraviolet-sensitive organic insulating material may be used as the material for the gate insulating film. Openings may be formed by exposing and developing the insulating material through a photomask.

<Steps of Forming Source Electrode and Drain Electrode>

Next, during Step 1 of forming the source electrode 30 and the drain electrode 40, a stacked film, which is formed of a first conductive film and a second conductive film, is formed via sputtering, CVD, vacuum deposition, or the like, for example, on the entire insulating substrate 19 on which the gate insulating layer 21 was formed. At such time, Ti, for example, which is a metal that adheres well to the gate insulating layer 21, can be used in the first conductive film and formed at a thickness of approximately 5 nm. Cu, which has a low electrical resistance, can be used as the second conductive film and formed at a thickness of approximately 200 nm.

The respective thicknesses of the first conductive film and the second conductive film are not limited to the above-described examples. The thickness of the first conductive film can be approximately 5 nm to 30 nm, for example, and the thickness of the second conductive film can be approximately 100 to 400 nm, for example. In addition, the materials used in the first conductive layer and the second conductive layer are not limited to Ti and Cu.

Next, a photosensitive resin film is applied via spin coating, and a resist pattern is formed by subsequently exposing and developing the photosensitive resin film. Next, the stacked film, which consists of the first conductive film and the second conductive film, that is protruding from the resist pattern is removed via wet etching. Afterwards, the first conductive layer 31, 41, the second conductive layer 32, 42, and the signal wiring line 15 are formed by submerging the resist pattern in an etching fluid and removing the resist pattern.

When wet etching is performed on the stacked film formed of the first conductive film and the second conductive film, an HF or oxidizing etchant can be used to etch Ti films, while a hydrogen peroxide etchant can used to etch Cu films.

The pattern formation method of the first electrode layer and the second electrode layer is not limited to the above-described method, and electroplating, electroless plating, printing that uses a conductive paste, or the like, can also be used.

FIG. 6 illustrates Step 2 of forming the source electrode and the drain electrode. Next, as shown in FIG. 6, during Step 2 of forming the source electrode and the drain electrode, a photosensitive resin film is applied via spin coating. By subsequently exposing and developing the photosensitive resin film, a resist pattern 60 is formed so to cover the insulating substrate 19 except for a region on which the third conductive layer will be formed.

FIG. 7 illustrates Step 3 of forming the source electrode and the drain electrode. Next, as shown in FIG. 7, during Step 3 of forming the source electrode and the drain electrode, a third conductive film 61 is formed via sputtering, CVD, vacuum deposition or the like, for example, on the entire insulating substrate 19 on which the resist pattern 60 was formed so as to cover the insulating substrate 19 except for the region on which the third conductive layer will be formed. The third conductive film 61 can be formed at a thickness of approximately 100 nm to 400 nm.

Metals such as platinum, nickel, gold, cobalt, palladium, silver, copper, molybdenum, and the like can be used as the materials to form the third conductive film 61 when a p-type organic semiconductor is used in the organic semiconductor layer 50. When an n-type organic semiconductor is used in the organic semiconductor layer 50, strontium, calcium, neodymium, magnesium, hafnium, barium, or the like can be used.

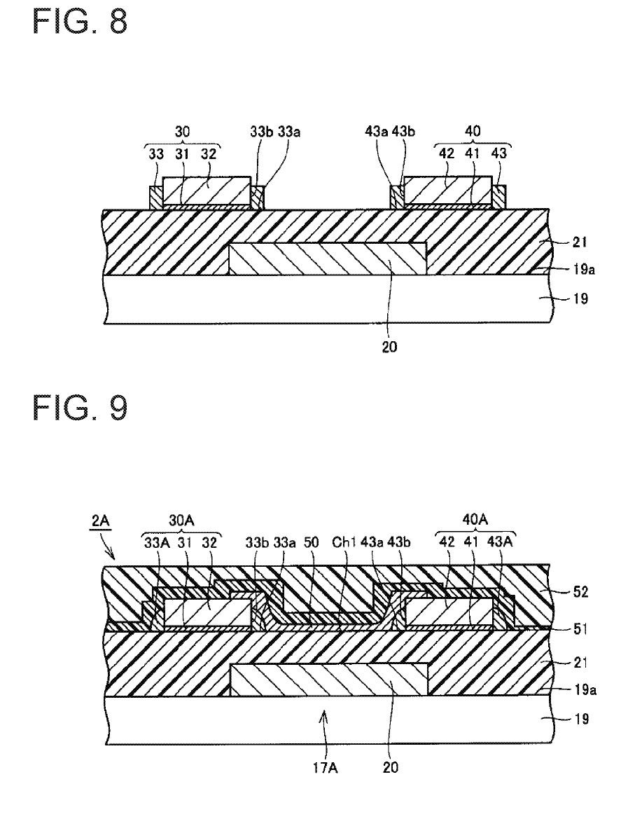

FIG. 8 illustrates Step 4 of forming the source electrode and the drain electrode. Next, as shown in FIG. 8, during Step 4 of forming the source electrode and the drain electrode, a step of lifting off, in which the insulating substrate 19 on which the third conductive film 61 was formed is submerged in an etching fluid, is used to remove the resist pattern 60. Unnecessary portions of the third conductive layer 61 formed on the resist pattern 60 are removed at the same that the resist pattern 60 is removed. As a result, the third conductive layer 33, 43 is formed at prescribed locations on the gate insulating layer 21, thereby forming the source electrode 30 and the drain electrode 40 on the gate insulating layer 21.

The third conductive layer 33, 43 is formed so as to contact a side face of the first conductive layer 31, 41 and a side face of the second conductive layer 32, 42 in the direction in which the source electrode 30 and the drain electrode 40 are arranged.

<Step of Forming Organic Semiconductor Layer>

Next, the entire insulating substrate 19, on which the source electrode 30 and the drain electrode 40 have been formed, is coated with an organic semiconductor material such as TIPS-pentacene, for example, and then baked at a temperature of approximately 100 to 150° C. for approximately several minutes to several dozen minutes. Afterwards, the organic semiconductor material is patterned using photolithography or the like. In this way, the organic semiconductor layer 50 is formed on the source electrode 30, the drain electrode 40, and the gate insulating layer 21 so as to cover at least a portion of the source electrode 30 and the drain electrode 40 and also cover the portion of the gate insulating layer 21 located between the source electrode 30 and the drain electrode 40. The organic semiconductor layer 50 can have a thickness of approximately 20 nm to 80 nm. The thin film transistor 17 of the present embodiment is formed by completing the above-mentioned steps.

<Step of Forming Passivation Film>

Next, a passivation film 51, which is made of an organic insulating film, is formed as a surface protective layer, for example, at a thickness of approximately 0.2 to 1.0 μm on the surface of the gate insulating layer 21 and the surface of the thin film transistor 17 (in other words, the gate electrode 20, the organic semiconductor layer 50, the source electrode 30, and the drain electrode 40).

<Step of Forming Planarizing Film>

Next, the entire insulating substrate 19, on which the passivation film 51 has been formed, is coated with an ultraviolet-sensitive organic insulating film at a thickness of approximately 1.0 μm to 3.0 μm using spin coating or slit coating and then baked. This results in the formation of a film. Next, a planarizing film 52 is patterned by exposing and developing the organic insulating film through the photomask.

Furthermore, a contact hole C, which connects the pixel electrode 53 and the drain electrode 40, is provided by using the patterned planarizing film 52 as a mask and performing wet etching or dry etching on the passivation film 51.

Next, by forming the pixel electrodes, it is possible to manufacture the thin film transistor substrate 2 of the present embodiment.

If the various above-mentioned layers are formed on a plastic film substrate or a plastic film substrate placed on a glass substrate, it is possible to obtain a flexible thin film transistor substrate by either leaving the plastic film substrate as is or by removing the plastic film substrate from the glass substrate.

### Embodiment 2

FIG. 9 is a schematic cross-sectional view of a thin film transistor substrate provided with a thin film transistor according to the present embodiment. A thin film transistor substrate 2A provided with a thin film transistor 17A according to the present embodiment will be described with reference to FIG. 9.

As shown in FIG. 9, the thin film transistor substrate 2A according to the present embodiment is substantially similar to the thin film transistor substrate 2 according to Embodiment 1, except for the fact that the shape of a third conductive layer 33A, 43A of a source electrode 30A and a drain electrode 40A in the thin film transistor 17A differs from the corresponding shape in Embodiment 1.

Specifically, the third conductive layer 33A, 43A, which is located so as to face the channel region Ch1, has a shape (a side wall shape) that protrudes in a direction moving away from the border of a first contact surface 33a, 43a and a second contact surface 33b, 43b. More specifically, the third conductive layer 33A, 43A located so as to face the channel region Ch1 has a curved face that curves such that the distance from the respective side faces of the first conductive layer 31, 41 and the second conductive layer 32, 42 facing the channel region Ch1 gradually increases moving toward the insulating substrate 19 along a direction normal to the insulating substrate 19.

Even when the third conductive layer 33A, 43A has such a shape, the third conductive layer 33A, 43A is formed of: a first contact surface 33a, 43a that contacts the gate insulating layer 21; and a second contact surface 33b, 43b that contacts a side face of the first conductive layer 31, 41 and a side face of the second conductive layer 32, 42 that are located so as to face the channel region Ch1. In this way, even in the thin film transistor 17A according to the present embodiment, it is possible to obtain a substantially similar effect to that of the thin film transistor 17 according to Embodiment 1.

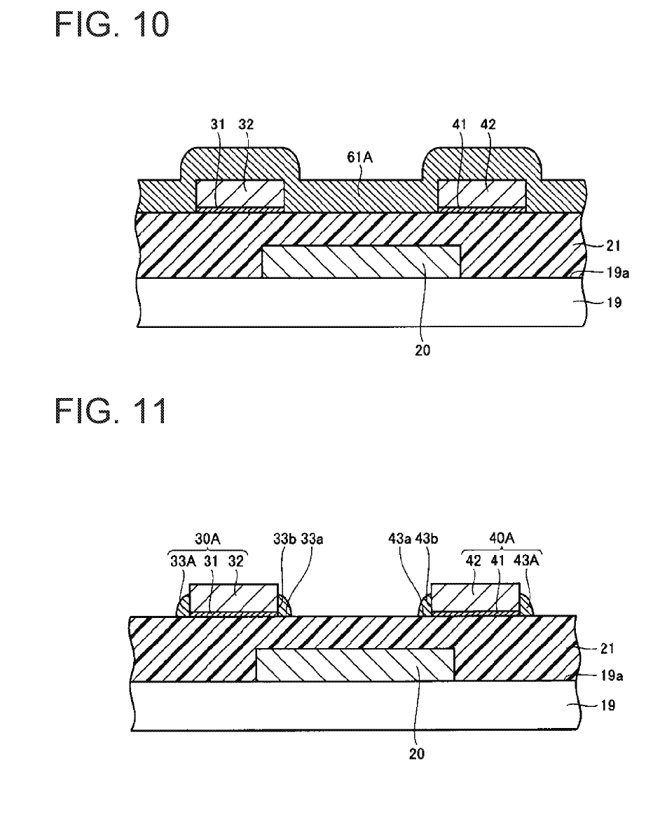

FIGS. 10 and 11 respectively illustrate Steps 2A and 3A of forming the source electrode and the drain electrode during the manufacturing process of the thin film transistor substrate shown in FIG. 9. A method of manufacturing the thin film transistor substrate 2A of the present embodiment will be described with reference to FIGS. 10 and 11.

The method of manufacturing the thin film transistor substrate 2A of the present embodiment is substantially similar to the method of manufacturing the thin film transistor substrate 2 of Embodiment 1, except for the fact that the formation steps of the source electrode and the drain electrode are different.

Specifically, the steps of forming the drain electrode and the source electrode in the method of manufacturing the thin film transistor substrate 2A of the present embodiment include Steps 2A and 3A instead of Steps 2 to 4 used to form the source electrode and the drain electrode in Embodiment 1.

In the method of manufacturing the thin film transistor substrate 2A according to the present embodiment, treatment similar to that used during the method of manufacturing the thin film transistor substrate according to Embodiment 1 is first performed during the step of forming the gate electrode, the step of forming the gate insulating layer, and Step 1 of forming the source electrode and the drain electrode, thereby forming a gate electrode 20, a gate insulating layer 21, a first conductive layer 31, 41, and a second conductive layer 32, 42 on the insulating substrate 19.

Next, as shown in FIG. 10, during Step 2A of forming the source electrode and the drain electrode, a third conductive film 61A is formed via sputtering, CVD, vacuum deposition, or the like, for example, across the entire insulating substrate 19 on which the first conductive layer 31, 41 and the second conductive layer 32, 42 have been formed. The third conductive film 61 can be formed at a thickness of approximately 100 nm to 400 nm.

When forming the third conductive film 61A, the third conductive film 61A may be formed in a direction that is angled with respect to the vertical direction of the insulating substrate 19 in order to improve the coverage of the side face of the first conductive layer 31, 41 and the side face of the second conductive layer 32, 42.

Next, as shown in FIG. 11, during Step 3A of forming the source electrode and the drain electrode, the third conductive layer 33A, 43A is formed in a side wall shape on the side face of the first conductive layer 31, 41 and the side face of the second conductive layer 32, 42 via anisotropic dry etching. In this manner, a source electrode 30A and a drain electrode 40A are formed on the gate insulating layer.

By performing anisotropic dry etching on the third conductive film 61A, it is possible to form the third conductive layer 33A, 43A by self-alignment. In this manner, compared to a method of using a mask and patterning the third conductive layer via photolithography or the like, it is possible to precisely form the third conductive layer without having to precisely adjust position. In addition, by omitting the step of photolithography, it is possible to easily manufacture a thin film transistor and reduce manufacturing costs.

In the present embodiment, an example was used in which the third conductive layer 33A, 43A was formed using only dry etching. The present invention is not limited to such a method, however, and the third conductive layer 33A, 43A may be formed by performing both dry etching and wet etching on the third conductive film 61A.

In such a case, it is preferable that, after performing dry etching on the third conductive film 61A such that the third conductive film 61A thinly covers the gate insulating film 21, the first conductive layer 31, 41, and the second conductive layer 32, 42, the remaining unnecessary portions of the third conductive film 61A on the gate insulating layer 21 and the second conductive layer 32, 42 be removed via wet etching. Thus, it is possible to prevent damage to the surface of the gate insulating film caused by dry etching.

Next, by performing processing similar to that of the method of manufacturing the thin film transistor according to Embodiment 1 during the step of manufacturing the organic semiconductor layer, it is possible to manufacture the thin film transistor 17A of the present embodiment.

Next, it is possible to manufacture the thin film transistor substrate 2A according to the present embodiment by performing processing similar to that of the method of manufacturing the thin film transistor according to Embodiment 1 during the step of forming the passivation film and the step of forming the planarizing film, and then forming the pixel electrodes.

### Embodiment 3

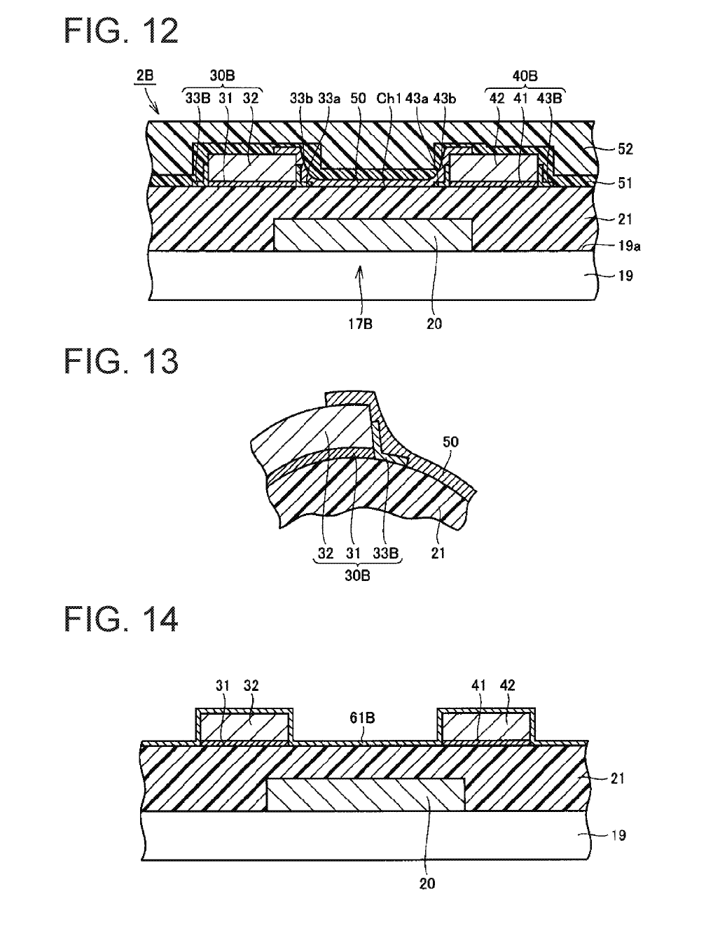

FIG. 12 is a schematic cross-sectional view of a thin film transistor substrate that includes a thin film transistor according to the present embodiment. FIG. 13 illustrates the state of a source electrode, an organic thin film semiconductor layer, and a gate insulating layer after the thin film transistor substrate shown in FIG. 12 has been bent. A thin film transistor substrate 2B that includes a thin film transistor 17B according to the present embodiment will be explained with reference to FIGS. 12 and 13.

As shown in FIG. 12, the configuration of the thin film transistor substrate 2B of the present embodiment is substantially similar to that of the thin film transistor substrate 2 according to Embodiment 1, except for the fact that the shape of the third conductive layer 33B, 43B of the source electrode 30B and the drain electrode 40B in the thin film transistor 17B is different.

Specifically, the third conductive layer 33B, 43B is formed of a portion that extends away from the gate insulating layer 21 along the side face of the first conductive layer 31, 41 and the side face of the second conductive layer 32, 42, and a portion that extends away from the first conductive layer 31, 41 along the gate insulating layer 21.

In this way, it is possible to ensure an adequately flexible substrate and prevent the third conductive layer 33B, 43B from rising up from the gate insulating layer 21 when the thin film transistor substrate 2B is bent.

If a thin film transistor substrate that has a third conductive layer having a rectangular cuboid shape different from the third conductive layer 33B, 43B of the present embodiment is bent so as to protrude upward while in contact with a side face of the first conductive layer 31, 41, a side face of the second conductive layer 32, 42, and the gate insulating layer 21, the third conductive layer will adhere more strongly to the side face of the first conductive layer 31, 41 and the side face of the second conductive layer 32, 42, which are metal layers, than the gate insulating layer 21, which is a resin layer. Thus, there is concern that the third conductive layer may be exposed to stress that will cause the third conductive layer to rise up from the gate insulating layer 21.

Thus, it is expected that the third conductive layer will rise up from the gate insulating layer when the thin film transistor substrate is bent, leading to mechanical stress in the organic semiconductor layer. It is anticipated that such a situation may lead to a decrease in mechanical strength and reliability.

However, since the third conductive layer 33B, 43B is formed so as to extend along a second direction on the thin film transistor substrate 2B of the present embodiment, it is possible to adequately take advantage of the ductility and malleability of the metal material in the third conductive layer 33B, 43B.

Thus, as shown in FIG. 13, even when the thin film transistor substrate 2B is bent so as to protrude upwards, the third conductive layer 33B, 43B will deform along with the bent first conductive layer 31, 41, second conductive layer 32, 42, and gate insulating layer 21. In this manner, it is possible to prevent the third conductive layer 33B, 43B from rising up from the gate insulating layer 21 when the thin film transistor substrate 2B is bent. As a result, it is possible to stabilize the operation of the thin film transistor 17B.

In addition, it is preferable that the thickness, in a direction normal to the insulating substrate 19, of a portion of the channel region-facing third conductive layer 33B, 43B that extends along the gate insulating layer 21 be less than or equal to ⅓ of the length (the distance from the side face of the first conductive layer 31, 41 that faces the channel region Ch1 to an end, which is located opposite to the side face of the first conductive layer 31, 41, of the portion of the third conductive layer 33B, 43B that extends along the gate insulating layer 21) extending along the gate insulating layer 21. In such a case, it is possible to further suppress the above-mentioned rising of the third conductive layer 33B, 43B.

In such a configuration, it is possible even in the thin film transistor 17B of the present embodiment to obtain an effect substantially similar to that of the thin film transistor 17 of Embodiment 1, and to stabilize the operation of the thin film transistor 17B even when the thin film transistor substrate is bent so as to protrude upward.

FIGS. 14 to 17 show Steps 2B to 5B of forming the source electrode and the drain electrode during the manufacturing process of the thin film transistor substrate shown in FIG. 12. A method of manufacturing the thin film transistor substrate 2B of the present embodiment will be described with reference to FIGS. 14 to 17.

The method of manufacturing the thin film transistor substrate 2B of the present embodiment is substantially similar to the method of manufacturing the thin film transistor substrate 2 of Embodiment 1, except for the fact that the formation steps of the source electrode and the drain electrode are different.

Specifically, the steps of forming the drain electrode and the source electrode in the method of manufacturing the thin film transistor substrate 2B of the present embodiment include Steps 2B to 5B instead of Steps 2 to 4 used to form the source electrode and the drain electrode in Embodiment 1.

In the method of manufacturing the thin film transistor substrate 2B according to the present embodiment, treatment similar to that used during the method of manufacturing the thin film transistor substrate according to Embodiment 1 is first performed during the step of forming the gate electrode, the step of forming the gate insulating layer, and Step 1 of forming the source electrode and the drain electrode, thereby forming a gate electrode 20, a gate insulating layer 21, a first conductive layer 31, 41, and a second conductive layer 32, 42 on the insulating substrate 19.

Next, as shown in FIG. 14, during Step 2B of forming the source electrode and the drain electrode, a third conductive film 61B is formed via sputtering, CVD, vacuum deposition, or the like, for example, across the entire insulating substrate 19 on which the first conductive layer 31, 41 and the second conductive layer 32, 42 have been formed.

At such time, it is preferable that the third conductive film 61B be formed at a thickness of approximately 5 nm to 50 nm, such that the thickness thereof is less than or equal to the thickness of the organic semiconductor layer 50 (see FIG. 12), and such that controllability of the thickness, adhesion with the gate insulating layer 21, and mechanical strength can be maintained.

When forming the third conductive film 61B, the third conductive film 61B may be formed in a direction that is angled with respect to the vertical direction of the insulating substrate 19 in order to improve the coverage of the side face of the first conductive layer 31, 41 and the side face of the second conductive layer 32, 42.

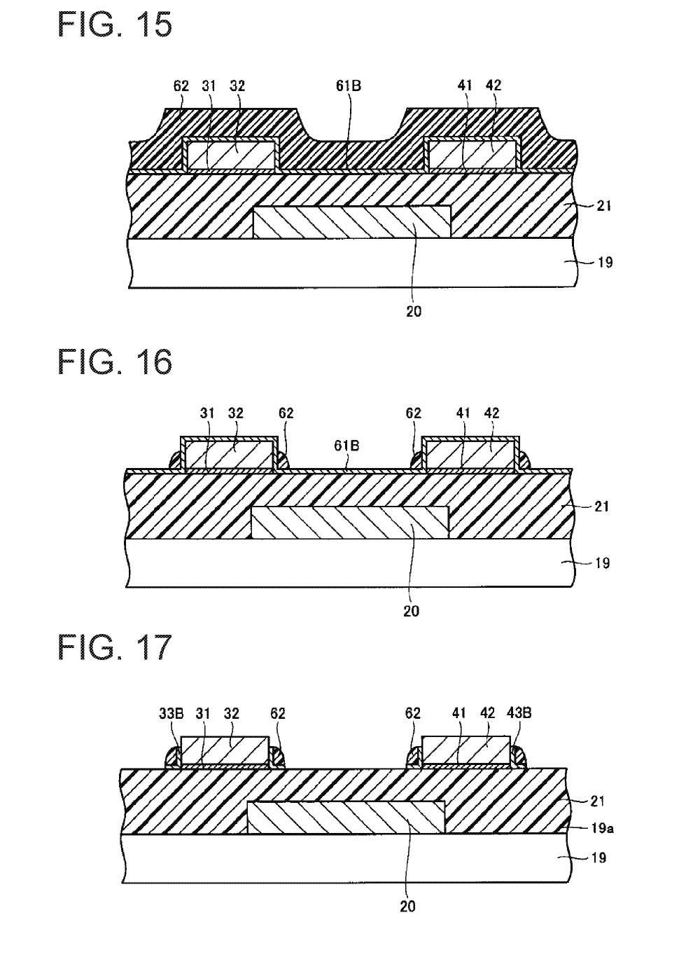

Next, as shown in FIG. 15, during Step 3B of forming the source electrode and the drain electrode, the entire insulating substrate 19, on which the third conductive film 61B has been formed, is coated via spin coating with a resist made of a photosensitive resin film or the like and then baked. It is preferable that the thickness of a resist film 62 formed after baking be thinner than in cases in which the film is formed via photolithography, and that the thickness be approximately 200 nm to 600 nm.

Next, as shown in FIG. 16, during Step 4B of forming the source electrode and the drain electrode, a side wall-shaped resist film 62 is formed via anisotropic dry etching so as to cover portions of the third conductive film 61B that correspond to the third conductive layer 33B, 43B. At such time, it is preferable that oxygen, CF₄, CHF₃, or the like be used as the etching gas, and that the pressure inside the etching chamber be 1 Torr to 1 mTorr.

The method for etching the resist film 62 is not limited to dry etching. Dry etching and wet etching may both be used, or wet etching may be used after dry etching has been performed on the resist film 62.

Next, as shown in FIG. 17, the third conductive film 61B is patterned via wet etching, with the side wall-shaped resist film 62 functioning as a mask that covers the portions of the third conductive film 61B that correspond to the third conductive layer 33B, 43B. Thereafter, by removing the side wall-shaped resist film 62, the third conductive layers 33B, 43B are formed so as to contact the side face of the first conductive layer 31, 41 and the side face of the second conductive layer 32, 42 in the direction in which the source electrode 30 and the drain electrode 40 are aligned.

Next, by performing processing similar to that of the method of manufacturing the thin film transistor according to Embodiment 1 during the step of manufacturing the organic semiconductor layer, it is possible to manufacture the thin film transistor 17B of the present embodiment.

Next, it is possible to manufacture the thin film transistor substrate 2B according to the present embodiment by performing processing similar to that of the thin film transistor according to Embodiment 1 during the step of forming the passivation film and the step of forming the planarizing film and then forming the pixel electrodes.

### Embodiment 4

FIG. 18 is a schematic cross-sectional view of a thin film transistor substrate that includes a thin film transistor according to the present embodiment. A method of manufacturing a thin film transistor substrate 2C that includes a thin film transistor 17C according to the present embodiment will be explained with reference to FIG. 18.

As shown in FIG. 18, the thin film transistor substrate 2C according to the present embodiment differs from the thin film transistor substrate 2C according to Embodiment 1 in that the thin film transistor 17C has a top-gate structure. Everything else, such as the materials used to form this structure, is the same as in Embodiment 1, however.

Specifically, the thin film transistor 17C according to the present embodiment includes: an insulating substrate 19 having a main surface 19a; a source electrode 30 and a drain electrode 40 provided so as to face each other on the main surface 19a; an organic semiconductor layer 50 provided so as to cover a portion of the substrate 19 located between the source electrode 30 and the drain electrode 40, and so as straddle the source electrode 30 and the drain electrode 40 from the top of the source electrode 30 to the top of the drain electrode 40; a gate insulating layer 21 provided above the main surface 19a so as to cover the source electrode 30, the drain electrode 40, and the organic semiconductor layer 50; and a gate electrode 20 provided on the gate insulating layer 21 so as to overlap, through the gate insulating layer 21, at least a portion of the source electrode 30 and a portion of the drain electrode 40, and also overlap the organic semiconductor layer 50 located between the source electrode 30 and the drain electrode 40.

The organic semiconductor layer 50 includes a channel region Ch2 formed so as to overlap the gate electrode 20 between the source electrode 30 and the drain electrode 40.

The source electrode 30 includes: a first conductive layer 31; a second conductive layer 32; and a third conductive layer 33. The drain electrode also includes: a first conductive layer 41; a second conductive layer 42; and a third conductive layer 43.

The first conductive layer 31, 41 is formed on the insulating substrate 19, and is formed using a material which adheres well to the insulating substrate 19, which is the base layer.

The second conductive layer 32, 42 is formed on the first conductive layer 31, 41. The second conductive layer 32, 42 is formed of a material that has a lower electrical resistance than the first conductive layer 31.

The third conductive layer 33 is formed on the channel region Ch2 side of the first conductive layer 31 and the second conductive layer 32, and is formed of a material that forms good ohmic contact with the organic semiconductor layer 50.

The third conductive layer 33, 43 has a substantially rectangular cuboid shape, and includes: a first contact surface 33a, 43a that contacts the main surface of the insulating substrate 19; and a second contact surface 33b, 43b that contacts a side face of the first conductive layer 31, 41 and a side face of the second conductive layer 32, 42 that respectively face the channel region Ch2.

By using such a configuration, even in the thin film transistor 17C according to the present embodiment, it is possible to obtain a substantially similar effect to that of the thin film transistor 17 according to Embodiment 1.

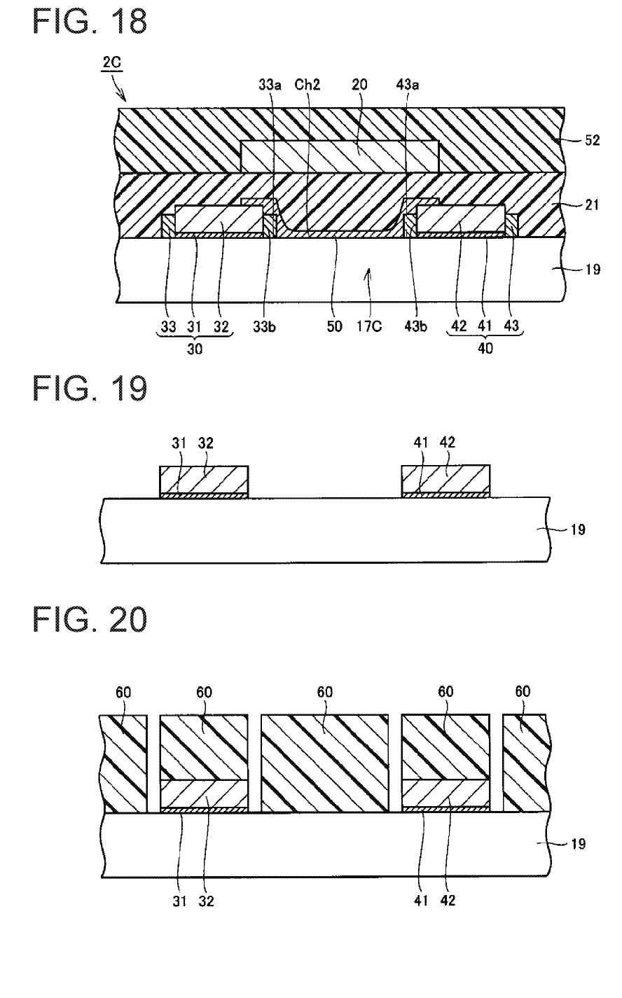

FIGS. 19 to 22 show Steps 1C to 4C of forming the source electrode and the drain electrode during the manufacturing process of the thin film transistor substrate shown in FIG. 18. FIG. 23 shows the state of the insulating substrate during the manufacturing process of the thin film transistor substrate shown in FIG. 18 after completion of the step of forming an organic semiconductor layer, the step forming a gate insulating layer, the step of forming a gate electrode, and the step of forming a planarizing film. The method of manufacturing the thin film transistor substrate 2C that includes the thin film transistor 17C according to the present embodiment will be explained with reference to FIGS. 19 to 23.

The method of manufacturing the thin film transistor substrate 2C according to the present embodiment is different from the method of manufacturing the thin film transistor substrate 2 according to Embodiment 1 in that after the source electrode 30, the drain electrode 40, and the organic semiconductor layer 50 are formed on the insulating substrate 19, the gate insulating layer 21 and then the gate electrode 20 are formed.

The method of forming the source electrode 30, the drain electrode 40, the organic semiconductor layer 50, the gate insulating layer 21, and the gate electrode 20 is substantially similar to Embodiment 1. A detailed description thereof will therefore be omitted.

First, as shown in FIG. 19, during Step 1C of forming the source electrode 30 and the drain electrode 40, a first conductive film and a second conductive film are formed on the main surface 19a of the insulating substrate 19 via sputtering, CVD, vacuum deposition, or the like. Thereafter, by patterning the stacked film made of the first conductive film and the second conductive film into a prescribed shape, the first conductive layer 31, 41 is formed on the insulating substrate 19, and the second conductive layer 32, 42 is then formed on the first conductive layer 31, 41. In addition, at such time, signal wiring lines are also formed.

Next, as shown in FIG. 20, during Step 2C of forming the source electrode 30 and the drain electrode 40, by coating the entire insulating substrate 19, on which the first conductive layer 31, 41 and the second conductive layer 32, 42 have been respectively formed, with a photosensitive resin, and then exposing and developing the photosensitive resin, a resist pattern 60 is formed so as to cover the substrate 19 except for the regions in which the third conductive layer will be formed.

Next, as shown in FIG. 21, during Step 3C of forming the source electrode 30 and the drain electrode 40, the third conductive film 61 is formed via sputtering, CVD, vacuum deposition, or the like, for example, over the entire insulating substrate 19 on which the resist pattern 60 has been formed.

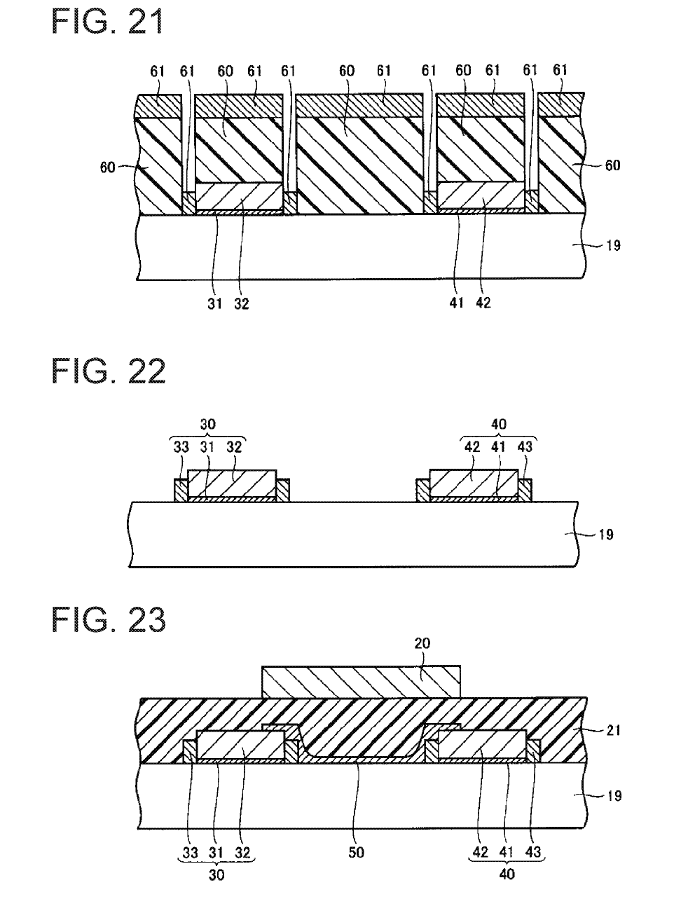

Next, as shown in FIG. 22, a step of lifting off, in which the insulating substrate 19 on which the third conductive film 61 has been formed is submerged in an etching fluid, is performed, thereby removing the resist pattern 60 and forming the third conductive layer 33, 43. In this manner, the source electrode 30 and the drain electrode 40 are formed on the main surface of the insulating substrate 19.

Next, as shown in FIG. 23, after the entire insulating substrate 19, on which the source electrode 30 and the drain electrode 40 have been formed, is coated with an organic semiconductor material and then baked, the organic semiconductor material is patterned. In this manner, the organic semiconductor layer 50 is formed (the step of forming the organic semiconductor layer).

Next, a gate insulating film is formed by coating the entire insulating substrate 19 on which the organic semiconductor layer 50 was formed with an organic insulating material and then baking the coated substrate 19. Next, the gate insulating film is patterned (step of forming the gate insulating layer). At this time, openings are formed in the gate insulating layer such that it is possible for the relay wiring lines and the signal wiring lines to be electrically connected.

Next, a gate electrode film is formed via sputtering on the entire insulating substrate 19 on which the gate insulating layer 21 has been formed. The gate electrode 20, scan wiring lines 14, and relay wiring lines 14a are formed by using photolithography to pattern the gate electrode film into a prescribed shape (step of forming the gate electrode). In this manner, the thin film transistor 17C according to the present embodiment is manufactured.

Next, a planarizing film is formed by coating the entire insulating substrate 19, on which the gate insulating layer 21 has been formed, with an ultraviolet-sensitive organic insulating film, and then baking the film-covered substrate 19. Thereafter, the planarizing film 52 is patterned (step of forming the planarizing film).

Furthermore, a contact hole C, which connects the pixel electrode 53 and the drain electrode 40, is provided by using the patterned planarizing film 52 as a mask and performing wet etching or dry etching on the gate insulating layer 21.

Next, by forming the pixel electrodes 53, it is possible to manufacture the thin film transistor substrate 2C of the present embodiment.

### Embodiment 5

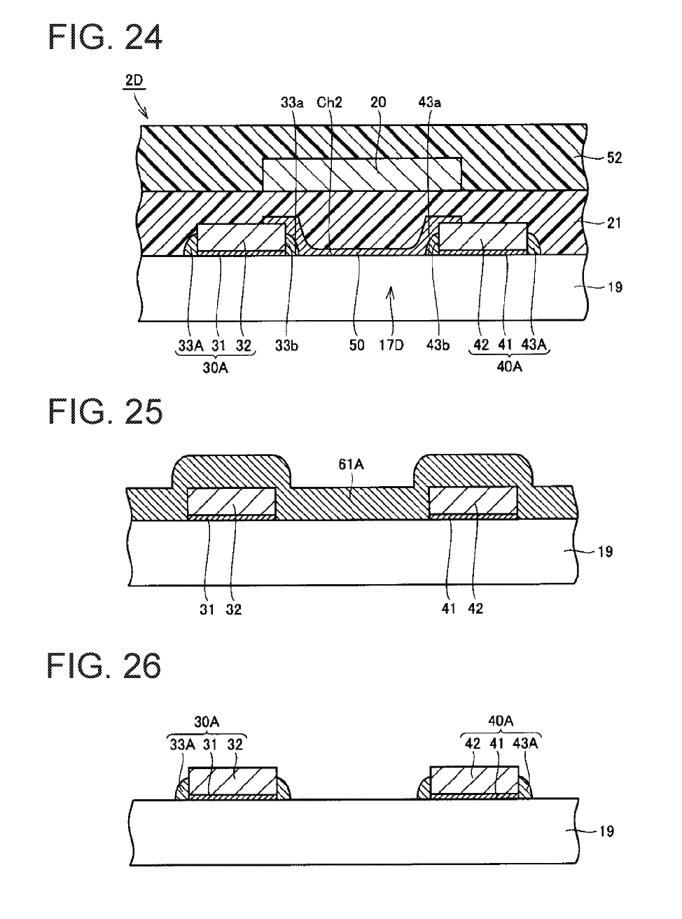

FIG. 24 is a schematic cross-sectional view of a thin film transistor substrate that includes a thin film transistor according to the present embodiment. A method of manufacturing a thin film transistor substrate 2D that includes a thin film transistor 17D according to the present embodiment will be explained with reference to FIG. 24.

As shown in FIG. 24, the thin film transistor substrate 2D according to the present embodiment is substantially similar to the thin film transistor substrate 2C according to Embodiment 4, except that the shape of the third conductive layer 33A, 43A of the source electrode 30A and the drain electrode 40A of the thin film transistor 17C is different.

Specifically, the third conductive layer 33A, 43A, which is located so as to face the channel region Ch2, has a shape (a side wall shape) that protrudes in a direction moving away from the border of a first contact surface 33a, 43a and a second contact surface 33b, 43b, for example. More specifically, the third conductive layer 33A, 43A includes a curved face that curves such that the distance from the side face of the first conductive layer 31, 41 and the side face of the second conductive layer 32, 42, which respectively face the channel region Ch2, gradually increases moving toward the insulating substrate 19 in a direction normal to the insulating substrate 19.

Even when the third conductive layer 33A, 43A has such a shape, the third conductive layer 33A, 43A is formed of: a first contact surface 33a, 43a that contacts the gate insulating layer 21; and a second contact surface 33b, 43b that contacts a side face of the first conductive layer 31, 41 and a side face of the second conductive layer 32, 42 that are located so as to face the channel region Ch2.

By using such a configuration, even in the thin film transistor 17D according to the present embodiment, it is possible to obtain a substantially similar effect to that of the thin film transistor 17C according to Embodiment 4.

FIGS. 25 and 26 respectively show Steps 2D and 3D of forming the source electrode and the drain electrode during the manufacturing process of the thin film transistor shown in FIG. 24. The method of manufacturing the thin film transistor substrate 2D according to the present embodiment will be explained with reference to FIGS. 25 and 26.

The method of manufacturing the thin film transistor substrate 2D according to the present embodiment is substantially similar to the method of manufacturing the thin film transistor substrate 2C according to Embodiment 4, except that the process of forming the source electrode and the drain electrode is different.

Specifically, the process of forming the source electrode and the drain electrode during the manufacturing process of the thin film transistor substrate 2D according to the present embodiment includes Steps 2D and 3D instead of Steps 2C to 4C included in the process of the forming the source electrode and the drain electrode in Embodiment 4.

Steps 2D and 3D for forming the source electrode and the drain electrode during the manufacturing process of the thin film transistor substrate 2D according to the present embodiment are substantially similar to Steps 2A and 3A for forming the source electrode and the drain electrode included in the manufacturing process of the thin film transistor substrate 2A according to Embodiment 2. A detailed description thereof will therefore be omitted.

First, during Step 1C of forming the source electrode and the drain electrode during the manufacturing process of the thin film transistor substrate 2D according to the present embodiment, the first conductive layer 31, 41 and the second conductive layer 32, 42 are formed on the insulating substrate 19 by performing treatment similar to that carried out during the manufacturing process of the thin film transistor substrate according to Embodiment 4.

Next, as shown in FIG. 25, during Step 2D of forming the source electrode and the drain electrode, a third conductive film 61A is formed via sputtering, CVD, vacuum deposition, or the like on the entire insulating substrate 19 on which the first conductive layer 31, 41 and the second conductive layer 32, 42 have been formed.

Next, as shown in FIG. 26, during Step 3D of forming the source electrode and the drain electrode, a side wall-shaped third conductive layer 33A, 43A is formed via anisotropic dry etching on the side face of the first conductive layer 31, 41 and the side face of the second conductive layer 32, 42. In this manner, the source electrode 30A and the drain electrode 40A are formed on the gate insulating layer.

Next, it is possible to produce the thin film transistor 17D according to the present embodiment by performing treatment similar to that carried out during the manufacturing process of the thin film transistor according to Embodiment 4 during the step of forming the organic semiconductor layer.

Next, it is possible to form the thin film transistor substrate 2D according to the present embodiment by forming pixel electrodes after performing treatment similar to that carried out during the manufacturing process of the thin film transistor according to Embodiment 4 during the step of forming the gate insulating layer, the step of forming the gate electrode, and the step of forming the planarizing film.

### Embodiment 6

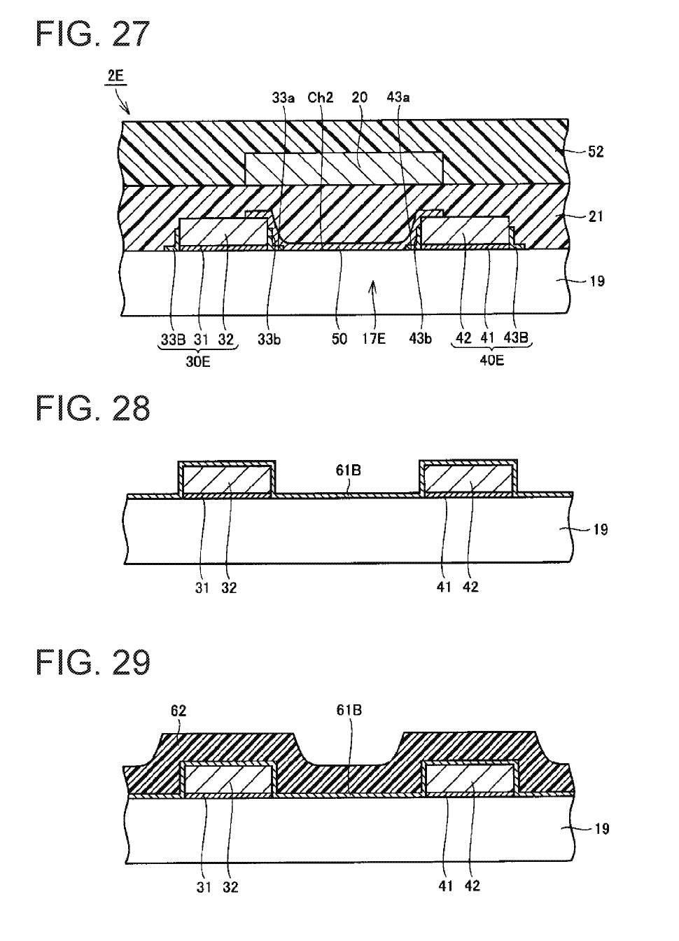

FIG. 27 is a schematic cross-sectional view of a thin film transistor substrate that includes a thin film transistor according to the present embodiment. A method of manufacturing a thin film transistor substrate 2E that includes a thin film transistor 17E according to the present embodiment will be explained with reference to FIG. 27.

As shown in FIG. 27, the thin film transistor substrate 2E according to the present embodiment is substantially similar to the thin film transistor substrate 2C according to Embodiment 4, except that the shape of a third conductive layer 33B, 43B of a source electrode 30B and a drain electrode 40B of the thin film transistor 17C is different.

Specifically, the third conductive layer 33B, 43B is formed of a portion that extends along the side face of the first conductive layer 31, 41 and the side face of the second conductive layer 32, 42 in a direction opposite to the gate insulating layer 21, and a portion that extends along the gate insulating layer 21 in a direction opposite to the first conductive layer 31, 41.

In this way, it is possible to ensure an adequately flexible substrate and prevent the third conductive layer 33B, 43B from rising up from the gate insulating layer 21 when the thin film transistor substrate 2E is bent. As a result, in the thin film transistor 17E of the present embodiment, the operation of the transistor is stabilized even when the thin film transistor substrate 2E that includes the thin film transistor 17E is bent.

As a result of such a configuration, it is possible to obtain a substantially similar effect to that of the thin film transistor substrate 17D of Embodiment 4 in the thin film transistor 17E of the present embodiment, and it is also possible to stabilize the operation of the thin film transistor 17E even when the thin film transistor substrate is bent so as to protrude upward.

FIGS. 28 to 31 show Steps 2E to 5E of forming the source electrode and the drain electrode during the manufacturing process of the thin film transistor substrate shown in FIG. 27. The method of manufacturing the thin film transistor substrate 2E according to the present embodiment will be described with reference to FIGS. 28 to 31.

The method of manufacturing the thin film transistor substrate 2E according to the present embodiment is substantially similar to the method of manufacturing the thin film transistor substrate 2C according to Embodiment 4, except that the steps of forming the source electrode and the drain electrode are different.

Specifically, the process of forming the source electrode and the drain electrode during the manufacturing process of the thin film transistor substrate 2E according to the present embodiment includes Steps 2E to 5E instead of Steps 2C to 4C included in the process of forming the source electrode and the drain electrode in Embodiment 4.

Steps 2E to 5E of forming the source electrode and the drain electrode during the manufacturing process of the thin film transistor substrate 2E according to the present embodiment are substantially similar to Steps 2B and 3B for forming the source electrode and the drain electrode during the manufacturing process of the thin film transistor substrate 2B according to Embodiment 3. A detailed description thereof will therefore be omitted.

First, during Step 1C of forming the source electrode and the drain electrode during the manufacturing process of the thin film transistor substrate 2E according to the present embodiment, the first conductive layer 31, 41 and the second conductive layer 32, 42 are formed on the insulating substrate 19 by performing treatment similar to that carried out during the manufacturing process of the thin film transistor substrate according to Embodiment 4.

Next, as shown in FIG. 28, during Step 2E of forming the source electrode and the drain electrode, a third conductive film 61B is formed via sputtering, CVD, vacuum deposition, or the like on the entire insulating substrate 19 on which the first conductive layer 31, 41 and the second conductive layer 32, 42 have been formed.

Next, as shown in FIG. 29, during Step 3E of forming the source electrode and the drain electrode, the entire insulating substrate 19, on which the third conductive film 61B has been formed, is coated with a resist made of a photosensitive resin film or the like and then baked, thereby forming a resist film 62.

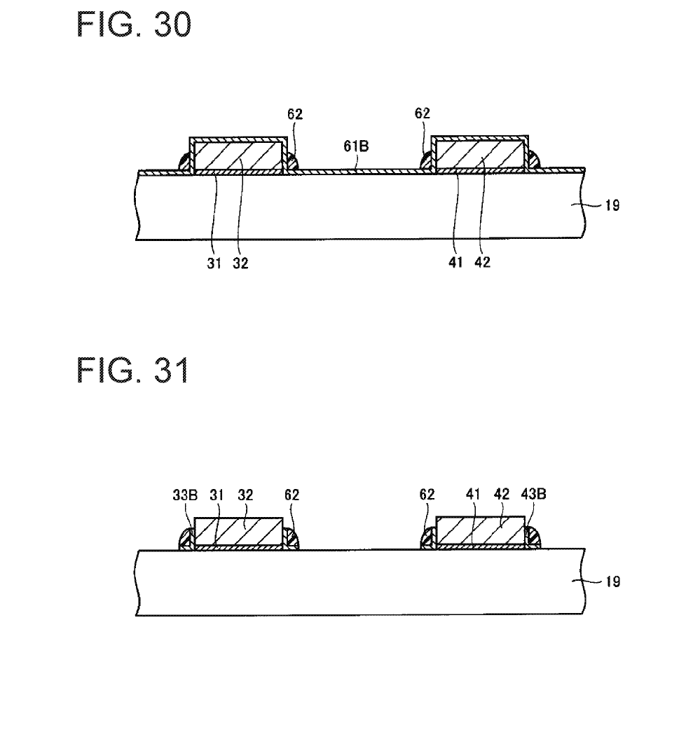

Next, as shown in FIG. 30, during Step 4E of forming the source electrode and the drain electrode, the resist film 62 is formed into a side wall shape via dry etching so as to cover a portion of the third conductive film 61B that corresponds to the third conductive layer 33B, 43B.

Next, as shown in FIG. 31, the third conductive film 61B is patterned by using the side wall-shaped resist film 62 as a mask to cover the portions of the third conductive film 61B corresponding to the third conductive layer 33B, 43B and then wet etching the third conductive film 61B. Thereafter, the third conductive layer 33B, 43B is formed, by removing the side wall-shaped resist film 62, so as to contact a side face of the first conductive layer 31, 41 and a side face of the second conductive layer 32, 42 in the direction in which the source electrode 30 and the drain electrode 40 are arranged.

The thin film transistor 17D according to the present embodiment can then be manufactured by performing processing similar to that carried out during the manufacturing process of the thin film transistor according to Embodiment 4 during the step of forming the organic semiconductor layer.

Next, it is possible to manufacture the thin film transistor substrate 2D according to the present embodiment by forming pixel electrodes after performing processing similar to that carried out during the manufacturing process of the thin film transistor according to Embodiment 4 during the step of forming the gate insulating layer, the step of forming the gate electrode, and the step of forming the planarizing film.

In the respective above-mentioned Embodiments 1 to 6, examples were used in which a liquid crystal display device that included a thin film transistor substrate was used as a display device. The present invention is not limited to this, however, and can be applied to another type of display device, such as an organic EL (electroluminescence) display device, an inorganic EL display device, an electrophoretic display device, or the like.

Embodiments of the present invention were described above, but all of the embodiments described above are illustrative in every respect and shall not be construed as limiting. The scope of the present invention is defined by the claims, and all modifications with the same meaning as the claims and within the scope defined thereby are included.

### DESCRIPTION OF REFERENCE CHARACTERS

1 liquid crystal display device

2, 2A, 2B, 2C, 2D, 2E thin film transistor substrate

3 opposite substrate

4 sealing member

5 liquid crystal layer

6, 7 polarizing plate

8 backlight unit

10 liquid crystal display panel

11 source driver

12 gate driver

13 control unit

14 scan wiring line

14a relay wiring line

15 signal wiring line

17, 17A, 17B, 17C, 17D, 17E thin film transistor

19 insulating substrate

19a main surface

20 gate electrode

21 gate insulating layer

30, 30A, 30B source electrode

31, 41 first conductive layer

32, 42 second conductive layer

33, 33A, 33B, 43, 43A, 43B third conductive layer

33a, 43a first contact surface

33b, 43b second contact surface

40, 40A, 40B drain electrode

50 organic semiconductor layer

51 passivation film

52 planarizing film

53 pixel electrode

53a source terminal

53b gate terminal

60 resist pattern

61, 61A, 61B third conductive film

62 resist film

1: A thin film transistor, comprising:
a substrate having a main surface;
a gate electrode provided on said main surface;
a gate insulating layer provided on said main surface so as to cover the gate electrode;
a source electrode and a drain electrode provided on the gate insulating layer so as to face each other and such that at least a portion of each overlaps the gate electrode through the gate insulating layer; and
an organic semiconductor layer provided so as to cover a portion of the gate insulating layer located between the source electrode and the drain electrode, and so as to straddle the source electrode and the drain electrode at respective tops thereof,
wherein the organic semiconductor layer includes a channel region formed so as to overlap the gate electrode between the source electrode and the drain electrode,
wherein the source electrode and the drain electrode each include: a first conductive layer that increases adhesion with the gate insulating layer; a second conductive layer that is stacked on the first conductive layer and that has an electrical resistance lower than the first conductive layer; and a third conductive layer that is provided on a side of the first conductive layer and a side of the second conductive layer, both of which face the channel region, the third conductive layer making ohmic contact with the organic semiconductor layer, and
wherein, in the source electrode and the drain electrode, the third conductive layer has a first contact surface that contacts the gate insulating layer, and a second contact surface that contacts a side face of the first conductive layer and a side face of the second conductive layer facing the channel region.

2: The thin film transistor according to claim 1, wherein the third conductive layer is formed of a portion that extends along the side face of the first conductive layer and the side face of the second conductive layer opposite to where the gate insulating layer is located, and a portion that extends along the gate insulating layer opposite to where the first conductive layer is located.

3: A thin film transistor, comprising:
a substrate having a main surface;
a source electrode and a drain electrode provided on the main surface so as to face each other;
an organic semiconductor layer provided so as to cover a portion of the substrate located between the source electrode and the drain electrode, and so as to straddle the source electrode and the drain electrode at respective tops thereof;
a gate insulating layer provided on the main surface so as to cover the source electrode, the drain electrode, and the organic semiconductor layer; and
a gate electrode provided on the gate insulating layer so as to overlap, through the gate insulating layer, at least a portion of the source electrode and the drain electrode, and the organic semiconductor layer located between the source electrode and the drain electrode,
wherein the organic semiconductor layer includes a channel region provided so as to overlap the gate electrode between the source electrode and the drain electrode,
wherein the source electrode and the drain electrode each include: a first conductive layer that increases adhesion with the substrate; a second conductive layer that is stacked on the first conductive layer and that has an electrical resistance lower than the first conductive layer; and a third conductive layer that is provided on a side of the first conductive layer and a side of the second conductive layer, both of which face the channel region, the third conductive layer making ohmic contact with the organic semiconductor layer, and
wherein, in the source electrode and the drain electrode, the third conductive layer has a first contact surface that contacts the main surface of the substrate, and a second contact surface that contacts a side face of the first conductive layer and a side face of the second conductive layer facing the channel region.

4: The thin film transistor according to claim 3, wherein the third conductive layer is formed of a portion that extends along the side face of the first conductive layer and the side face of the second conductive layer opposite to where the substrate is located, and a portion that extends along the substrate opposite to where the first conductive layer is located.

5: The thin film transistor according to claim 1, wherein the third conductive layer protrudes in a direction heading away from a border of the first contact surface and the second contact surface.

6: The thin film transistor according to claim 3, wherein the third conductive layer protrudes in a direction heading away from a border of the first contact surface and the second contact surface.
